(19) United States
(12) Patent Application Publication
(10) Pub. No.: US 2025/0069927 A1
(43) Pub. Date: Feb. 27, 2025

(54) DEVICE FOR PACKAGING WAFER CASSETTES

(71) Applicant: SILTRONIC AG, Munich (DE)

(72) Inventors: Franz SOLLINGER, Polling (DE); Maximilian ESTERL, Geratskirchen (DE); Jochen GAHN, Bad Birnbach (DE); Andreas KÖHLER, Kirchdorf (DE)

(21) Appl. No.: 18/937,065

(22) Filed: Nov. 5, 2024

Related U.S. Application Data
(63) Continuation of application No. PCT/EP2023/060652, filed on Apr. 24, 2023.

(30) Foreign Application Priority Data
May 5, 2022 (EP) 22171717

(51) Int. Cl. H01L 21/677; H01L 21/67; H01L 21/673

(52) U.S. Cl. CPC H01L 21/67769; H01L 21/67259; H01L 21/67282; H01L 21/67294; H01L 21/67386; H01L 21/67766

(57) ABSTRACT

An apparatus automatically packages wafer cassettes in a shipping box. The apparatus includes: a loading station configured to take the shipping box for semiconductor wafers; a radio-frequency identification (RFID) reader/writer configured to read and write to an RFID tag affixed to the shipping box; a camera configured to optically examine attachments to the shipping box; an element configured for equipping the shipping box with a desiccant pouch; an element configured for sealing a bag that surrounds the shipping box with a weld seam; an element configured for checking the impermeability of a weld seam; an element configured for applying labels to the shipping box; a robot arm configured to automatically transport the shipping box; an element configured for storing packaging material; and an element configured to take the shipping box for semiconductor wafers and to store the shipping box for transportation.

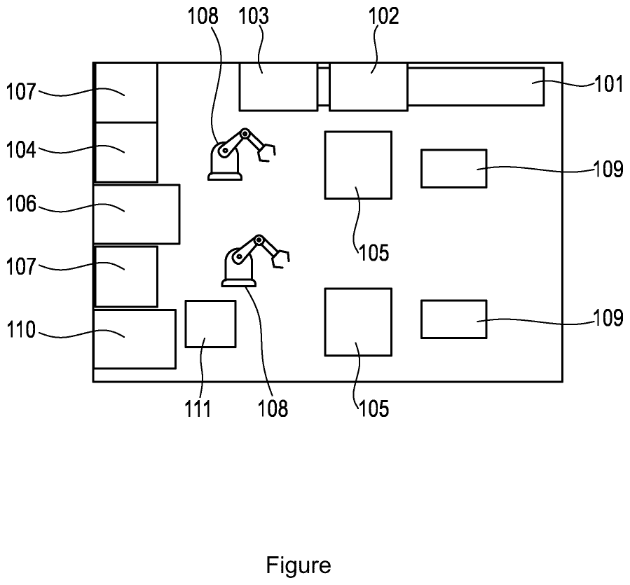

### CROSS REFERENCE TO RELATED APPLICATIONS

This application is a continuation of International Application No. PCT/EP2023/060652 (WO 2023/213596 A1), filed on Apr. 24, 2023, and claims benefit to European Patent Application No. EP 22171717, filed on May 5, 2022. The aforementioned applications are hereby incorporated by reference herein.

### FIELD

The subject matter of the present disclosure relates to packaging a wafer cassette and to a packaging apparatus for a wafer cassette that is capable of automatically packaging a wafer cassette.

### BACKGROUND

A wafer refers to a thin plate used as raw material for an integrated semiconductor circuit (IC), and is fabricated primarily using a silicon material.

A fabrication process for a semiconductor wafer made of silicon comprises a single-crystal growing process to fabricate a single-crystal silicon block, a cutting process to obtain a thin disc-like wafer by cutting a single-crystal block, an edge grinding process to machine an outer circumferential section of a wafer, in order to prevent cracks and deformations in the wafer obtained by way of the cutting process, a lapping process to remove damage remaining on a wafer due to the mechanical machining, in order to improve the evenness of the wafer, a polishing process to mirror-polish a wafer and a cleaning process to remove abrasives or foreign matter adhering to a semiconductor wafer.

The semiconductor wafers fabricated using these different processes are put into a cassette, e.g. a front open shipping box (FOSB), in order to avoid contaminants and to protect them from external influences. Before they are packaged and shipped, they are sealed externally using a packaging film.

Since the packaged semiconductor wafers need to be sent directly to the production line of the respective manufacturers of electronic devices and identified there, the quality of the packaging plays an extremely large part. Labels need to be positioned exactly and reproducibly, for example. The content of these labels also needs to match the content for each delivery exactly. Moreover, the semiconductor wafers need to be in the respective slots of the wafer cassette in the correct order. Moreover, different requirements of the different manufacturers of electronic devices need to be taken into account. By way of example, the labels need to be positioned differently depending on the customer or the content of the labels (in barcode or characters, or both) varies depending on the customer.

US 2020 219 741 A1 describes an apparatus for packaging wafer cassettes, wherein the apparatus comprises:
a loading part into which a wafer cassette is loaded; an accessory inspection part configured so that it examines a formula affixed to the wafer cassette and inspects accessories of the wafer cassette; a first label attachment part configured so that it attaches a first label to the wafer cassette on which the accessory inspection is complete; a primary film packing part configured so that it takes a primary film according to the formula and packages the wafer cassette using the primary film; a secondary film packaging part configured so that it takes a secondary film according to the formula and secondarily packages the wafer cassette using the secondary film; a second label attachment part configured so that it attaches a second label to the secondary film used to package the wafer cassette; and a discharge part configured so that it dispenses the wafer cassette that has been completely packaged.

JP 2015 058 958 A2 describes a packaging system that has a multiplicity of clamps for opening and closing the bag opening of a side gusset bag in a horizontal state, in which the bag opening is formed at one end, and a carriage arm for inserting a container or a packaging object into the side gusset bag.

None of the documents mentioned are fully able to provide an apparatus that is capable of solving the problems already mentioned.

### SUMMARY

In an embodiment, the present disclosure provides an apparatus that automatically packages wafer cassettes in a shipping box. The apparatus includes: a loading station configured to take the shipping box for semiconductor wafers; a radio-frequency identification (RFID) reader/writer configured to read and write to an RFID tag affixed to the shipping box; a camera configured to optically examine attachments to the shipping box; an element configured for equipping the shipping box with a desiccant pouch; an element configured for sealing a bag that surrounds the shipping box with a weld seam; an element configured for checking the impermeability of a weld seam; an element configured for applying labels to the shipping box; a robot arm configured to automatically transport the shipping box; an element configured for storing packaging material; and an element configured to take the shipping box for semiconductor wafers and to store the shipping box for transportation.

### BRIEF DESCRIPTION OF THE DRAWING

Subject matter of the present disclosure will be described in even greater detail below based on the exemplary figure. All features described and/or illustrated herein can be used alone or combined in different combinations. The features and advantages of various embodiments will become apparent by reading the following detailed description with reference to the attached drawing, which illustrates the following:

The FIGURE shows an exemplary form of an apparatus according to the present disclosure for packaging wafer cassettes.

### DETAILED DESCRIPTION

Aspects of the present disclosure provide an apparatus that minimizes the aforementioned problems and is also capable of increasing the throughput of the packaging installation.

The apparatus of the FIGURE comprises the following elements:
101 loading station capable of taking a shipping box for semiconductor wafers;
102 element for writing to and reading an RFID tag affixed to the shipping box;
103 element for optically examining attachments to the shipping box by means of a camera;
104 element for equipping the shipping box with a desiccant pouch;
105 element for sealing a bag that surrounds the shipping box by means of a weld seam;
106 element for checking the impermeability of a weld seam;
107 element for applying labels to a shipping box;
108 element for automatically transporting the shipping box in the form of a robot arm;
109 element for storing packaging material; and
110 element capable of taking a shipping box for semiconductor wafers and of storing said shipping box for transportation.

Detailed description of exemplary embodiments according to the invention present disclosure The apparatus according to the present disclosure for packaging wafer cassettes comprises multiple elements, which are described more accurately below.

The shipping boxes used are containers made from plastic, for example made from polycarbonate (PC), which may include components made from polybutylene terephthalate (PBT), polyolefin elastomers (POE) or poly(ethylethylene) (PEE). These shipping boxes are usually referred to as “front opening shipping boxes” (FOSB).

The apparatus according to the present disclosure comprises an automatic loading station (101) capable of taking a shipping box for semiconductor wafers.

The FOSB is set up on the loading station (101).

The apparatus according to the present disclosure further comprises an element for automatically writing to and reading an RFID tag affixed to the shipping box (102). Alternatively, precisely one RFID tag can also be used. An RFID tag (radio-frequency identification, “identification using electromagnetic waves”) denotes a technology for transceiver systems for automatically and contactlessly identifying and locating objects using radio waves.

The apparatus according to the present disclosure likewise comprises an element for automatically optically examining attachments to the shipping box by means of a camera (103). Any damage to the shipping box needs to be prevented, and it is therefore important to perform examinations in this regard. All the examination results, including the camera images, are stored.

The apparatus according to the present disclosure preferably contains an element for automatically checking that the wafer cassette has been filled correctly. The task of this element is for example to identify semiconductors that have been stowed incorrectly. The wafer cassette has a multiplicity of receiving slots spaced apart from one another for holding semiconductor wafers, each of which is prevented from further movement by a lower or upper pad. A common error can be what is known as a cross-slot error, where the semiconductor wafer has been stowed on the slant in the wafer box.

The apparatus according to the present disclosure furthermore preferably contains a printer for printing labels that are used for sticking on the box.

The apparatus according to the present disclosure also contains an apparatus for automatically applying the labels to the shipping box (107).

Furthermore, the apparatus according to the present disclosure preferably contains an element for automatically checking the labels affixed to the shipping box. The examination performed here is for example whether the labels are in the correct position and/or the printed contents are readable and the contents thereof match the desired content.

After the labels have been stuck on, a camera system is preferably used to check the position at which they have been stuck on with millimetre accuracy. The printed contents of the labels are likewise checked. All codes and characters need to be printed so as to be readable and error-free. Unprinted areas of the label must have no misprints. The label is compared with an image generated via print file using image comparison and is examined for a reproduction factor. All the test results are stored.

Similarly, the apparatus according to the present disclosure contains an apparatus for automatically sealing an inner bag that surrounds the shipping box by means of a first weld seam (105).

And the apparatus according to the present disclosure contains an element for automatically checking the impermeability of the first weld seam (106). This involves for example applying underpressure in order to check the impermeability of the weld seam. The packaged FOSB is tested for the degree of impermeability of the bag in a vacuum chamber by means of a filling gas test. The test result is stored in the EDP.

The apparatus according to the present disclosure additionally contains an element for automatically equipping the shipping box with a desiccant pouch (104). Desiccant pouches are generally filled with silica gel and are suitable for absorbing moisture from the air and thus avoiding the formation of condensation. According to a preferred embodiment, it is absolutely essential for the desiccant pouches to always be positioned at the same position in the shipping box. A desiccant pouch is automatically glued on.

The apparatus according to the present disclosure preferably also contains an element for sealing an outer bag that surrounds the shipping box by means of a second weld seam. The material used for the outer bag is usually different from the material that is used for the inner bag. After the bag has been folded shut, the air is drawn from the bag and an adjustable, defined amount of gas is supplied. The bag is then welded. The overlap of the bag is folded and glued.

The apparatus according to the present disclosure preferably contains an element for automatically checking the impermeability of the second weld seam. This preferably involves underpressure being used. The packaged FOSB is tested for the degree of impermeability of the bag in a vacuum chamber by means of a filling gas test. The test result is stored.

The apparatus according to the present disclosure additionally contains an element for automatically transporting the shipping box (108). Transportation apparatuses in the form of a robot arm are suitable for this.

Moreover, the apparatus according to the present disclosure contains an element that is capable of taking a shipping box for semiconductor wafers and of storing said shipping box for transportation.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. An apparatus for packaging wafer cassettes in a shipping box, the apparatus comprising:
a loading station configured to take the shipping box for semiconductor wafers;
a radio-frequency identification (RFID) reader/writer configured to read and write to an RFID tag affixed to the shipping box;
a camera configured to optically examine attachments to the shipping box;
an element configured to equip the shipping box with a desiccant pouch;
an element configured to seal a bag that surrounds the shipping box with a weld seam;
an element configured to check the impermeability of a weld seam;
an element configured to apply labels to the shipping box;
a robot arm configured to automatically transport the shipping box;
an element configured to store packaging material; and
an element configured to take the shipping box for semiconductor wafers and to store the shipping box for transportation.

2. A method for packaging wafer cassettes in a shipping box, the method comprising using the apparatus according to claim 1.

3. An apparatus for packaging a wafer cassette in a front opening shipping box (FSOB) having a radio-frequency identification (RFID) tag affixed thereto, the wafer cassette having a multiplicity of receiving slots spaced apart from one another and holding semiconductor wafers, each of which being prevented from further movement by a lower or upper pad, the apparatus comprising:
a transceiver system configured to automatically and contactlessly read from and write to the RFID tag;
a camera system comprising a camera configured for optical examination;
a printer configured to print labels;
a seam welder;
a vacuum chamber; and
a robot arm;
wherein the apparatus is configured to:
optically examine the shipping box and store images of the shipping box;
checking that the wafer cassette has been filled correctly with the semiconductor wafers;
print the label and attach the label to the FSOB;
check that the label is in a correct position, that contents of the label are readable, and that the contents of the label match predetermined content;
surround the FSOB with an inner bag and seal the inner bag with a first weld seam;
check a degree of impermeability of the first weld seam;
glue a desiccant pouch in a predetermined location on the FSOB;
surround the FSOB with an outer bag and seal the outer bag with a second weld seam, the outer bag being made from a material different than the inner bag; and
check a degree of impermeability of the second weld seam.

4. A method for packaging a wafer cassette, the method comprising:
obtaining a front opening shipping box (FSOB) having a radio-frequency identification (RFID) tag affixed thereto, the FSOB containing the wafer cassette, the wafer cassette having a multiplicity of receiving slots spaced apart from one another and holding semiconductor wafers, each of which being prevented from further movement by a lower or upper pad;
optically examining the shipping box using a camera, and storing images captured by the camera of the shipping box;
automatically checking that the wafer cassette has been filled correctly with the semiconductor wafers;
printing a label and attaching the label to the FSOB;
automatically checking that the label is in a correct position, that contents of the label are readable, and that the contents of the label match predetermined content;
surrounding the FSOB with an inner bag and sealing the inner bag with a first weld seam;
automatically checking a degree of impermeability of the first weld seam using a vacuum chamber and a filling gas test;
equipping the shipping box with a desiccant pouch by gluing the desiccant pouch in a predetermined location;
surrounding the FSOB with an outer bag and sealing the outer bag with a second weld seam, the outer bag being made from a material different than the inner bag; and
automatically checking a degree of impermeability of the second weld seam.
